(19) United States
(12) Patent Application Publication
(10) Pub. No.: US 2002/0090763 A1
(43) Pub. Date: Jul. 11, 2002

(54) Method of forming a substrate contact electrode in a SOI wafer

(76) Inventor: Hua-Chou Tseng, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/754,352

(22) Filed: Jan. 5, 2001

(51) Int. Cl. H01L 21/00; H01L 21/84; H01L 21/4763

(52) U.S. Cl. 438/149; 438/629

(57) ABSTRACT

The present invention provides a method of forming a substrate contact electrode in a silicon-on-insulator (SOI) wafer. The SOI wafer has a substrate, with a first insulator layer and a silicon layer covering the substrate, respectively. The method begins with the etching of a contact hole from the surface of the silicon layer through to the substrate and forming a second insulator layer covering the interior wall and the bottom surface within the contact hole. After removing portions of the second insulator layer from the bottom surface within the contact hole, a substrate contact plug is formed in the contact hole. Finally, a first ion implantation process is performed to form a well in the SOI wafer.

### BACKGROUND OF THE INVENTION

1. Field of the Invention

The present invention relates to a method of forming a substrate contact electrode, and more particularly, to a method of forming a substrate contact electrode in a silicon-on-insulator (SOI) wafer.

2. Description of the Prior Art

As the dimensional aspect of devices continue to decrease, the parasitic effects of MOS devices have become a critical factor in both device performance and circuit integrity. Recently, a silicon-on-insulator (SOI) substrate, normally formed by a Separation by Implantation Oxygen (SIMOX) method, has been developed as a solution. A metal-oxide-semiconductor field-effect transistor (MOSFET) formed on the SOI substrate is installed in a single crystal layer, and electrically isolated from an underlying silicon substrate by a silicon dioxide isolation layer; the structural layout of the MOSFET thereby prevents the latch up phenomenon of electrical devices and avoids electrical breakdown.

Please refer to FIG. 1 to FIG. 3 of the schematic diagrams of a shallow trench isolation (STI) process according to the prior art. As shown in FIG. 1, a semiconductor wafer 10 has a SOI substrate 12 and a silicon nitride layer 16, with an underlying silicon oxide layer 14 covering the SOI substrate 12. The SOI substrate 12 includes a silicon substrate 22 and an insulator layer 24, respectively. A silicon layer 26 covers the insulator layer 24. A silicon oxide layer 14 and a silicon nitride layer 16 are used as a pad oxide and a mask, respectively, in the following process.

The shallow trench isolation (STI) method according to the prior art involves first forming a shallow trench 18 in a predetermined area on the surface of the semiconductor wafer 10 by performing various processes, such as photolithography and etching. The shallow trench 18 is positioned through the silicon nitride layer 16, the silicon oxide layer 14, and the silicon layer 26, to a predetermined depth in the insulator layer 24 of the SOI substrate 12.

As shown in FIG. 2, due to damage of both the sidewall and the bottom surface of the shallow trench 18 during the etching process, lattice defects in the STI structure are produced. Thus, a thermal oxidation process, also known as a furnace oxidation process, is performed to oxidize the sidewall and the bottom surface of the shallow trench 18 in a temperature environment of 800 to 1000° C. to form a liner oxide layer 28 on the interior surface of the shallow trench 18. Another objective of the thermal oxidation process is corner-rounding the sharp corner portions located at the interface of the trench 18 as well as at the horizontal surface of the silicon substrate 26, to release stress and prevent leakage.

As shown in FIG. 3, a chemical vapor deposition (CVD) process is performed to form a dielectric layer 20 to smoothly cover the surface of the semiconductor 10 and to fill in the shallow trench 18 to insulate the shallow trench 18. Thereafter, a chemical mechanical polishing (CMP) process is performed to remove a portion of the dielectric layer 20, the silicon nitride layer 16, and the silicon oxide layer 14 on the surface of the silicon layer 26. The surface of the remaining portion of the dielectric layer 20 located within the shallow trench 18 is approximately aligned with that of the silicon layer 26 to form a smooth surface of the semiconductor layer 10 at the end of the STI process.

Although the STI process according to the prior art can achieve the required isolation, the bias of the SOI substrate cannot be adjusted. The operation of the device is thus limited by the accumulation of current caused by the insulator layer.

### SUMMARY OF THE INVENTION

It is therefore a primary object of the present invention to provide a method of forming a substrate contact electrode in a SOI wafer, more specifically, a method applied on a SOI wafer to enable bias adjustment of the SOI substrate.

In the present invention, a method of forming a substrate contact electrode in a SOI wafer first involves etching a contact hole from the surface of the silicon layer through to the substrate. By performing a thermal oxidation process and a CVD process, a second insulator layer covering the interior wall and the bottom surface within the contact hole is formed. After removing portions of the second insulator layer from the bottom surface within the contact hole, a substrate contact plug is formed within the contact hole, followed by the use of a first ion implantation process to form a well in the SOI wafer.

It is an advantage of the present invention over the prior art that the bias of the SOI substrate can be adjusted to prevent current accumulation due to the first insulator layer and increase the operational efficiency of the device.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWING

FIG. 1 to FIG. 3 are schematic diagrams of a shallow trench isolation process according to the prior art.

FIG. 4 to FIG. 9 are schematic diagrams of forming a substrate contact electrode in a SOI wafer according to the present invention.

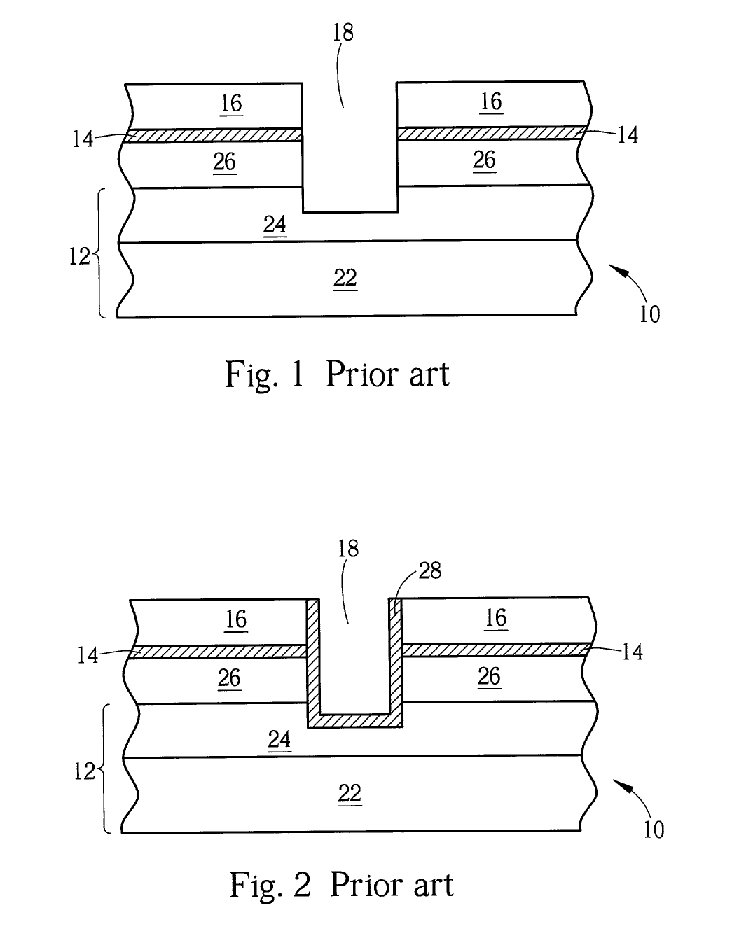

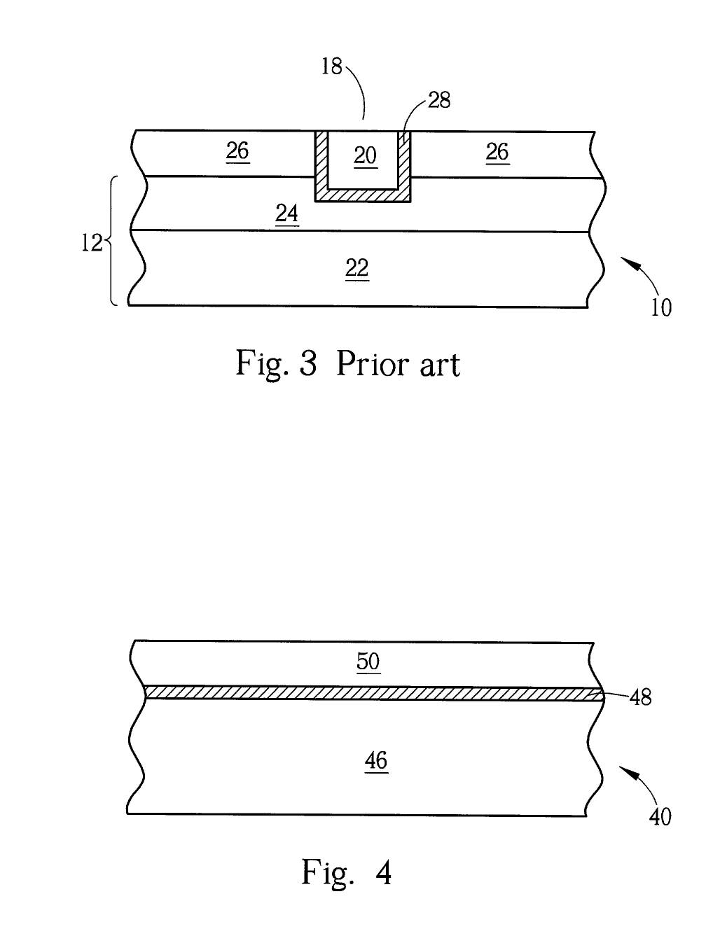

### DETAILED DESCRIPTION OF THE PREFERRED EMBODIMENT

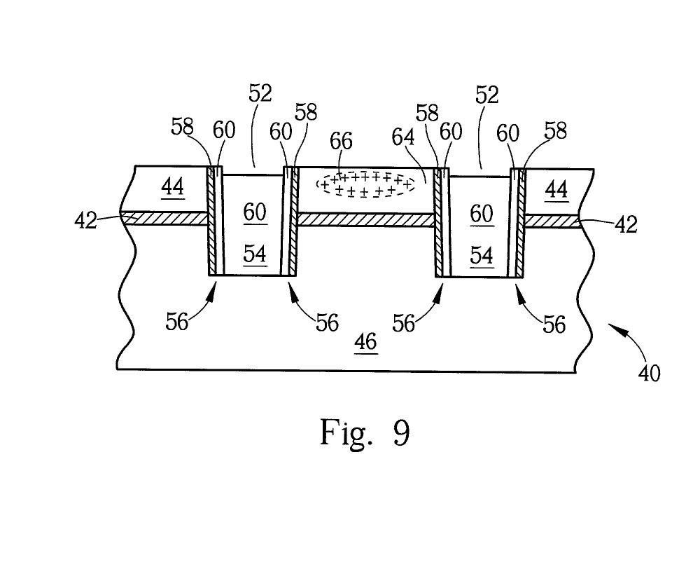

Please refer to FIG. 4 to FIG. 9 of schematic diagrams of forming a substrate contact electrode in a silicon-on-insulator (SOI) wafer, according to the present invention. As shown in FIG. 4, a SOI wafer 40 has a substrate 46, with a first insulator layer 48 and a silicon layer 50 covering the substrate 46, respectively. The thickness of the silicon layer 50 is approximately 1000 angstroms.

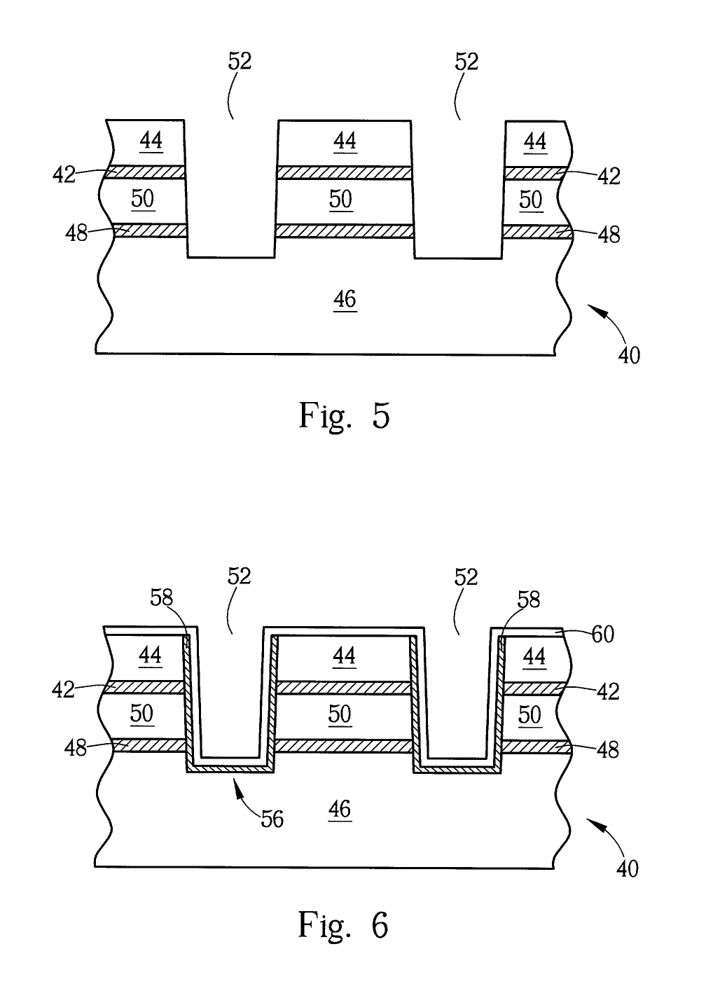

As shown in FIG. 5, a silicon nitride layer 44 is formed, with an underlying silicon oxide layer 42 covering the silicon layer 50. The silicon oxide layer 42 and the silicon nitride layer 44 are used as a pad oxide and a mask, respectively, in the following process. A photolithographic process is performed to form patterns of a contact hole 52 on the surface of the silicon nitride layer 44. The contact hole 52, of a predetermined depth, is thus formed in the silicon layer 50 via a chemical vapor deposition (CVD) process and an etching process using the remaining portions of the silicon nitride layer 44 as a hard mask.

Due to damage of both the sidewall and the bottom surface of the contact hole 52 during the etching process, lattice defects causing stress and current leakage in the active area, as well as impurity in the following gap filling process, are produced. Thus, a second insulator layer 56, having a liner oxide layer 58 and a liner nitride layer 60, is formed on the interior surface of the contact hole 52, as shown in FIG. 6. The liner oxide layer 58 is formed on the interior surface of the contact hole 52 via a thermal oxidation process, also known as a furnace oxidation process, in a temperature environment of 800 to 1000° C. , followed by a chemical vapor deposition (CVD) process to form the liner nitride layer 60 on the surfaces of the liner oxide layer 58 and the SOI wafer 40.

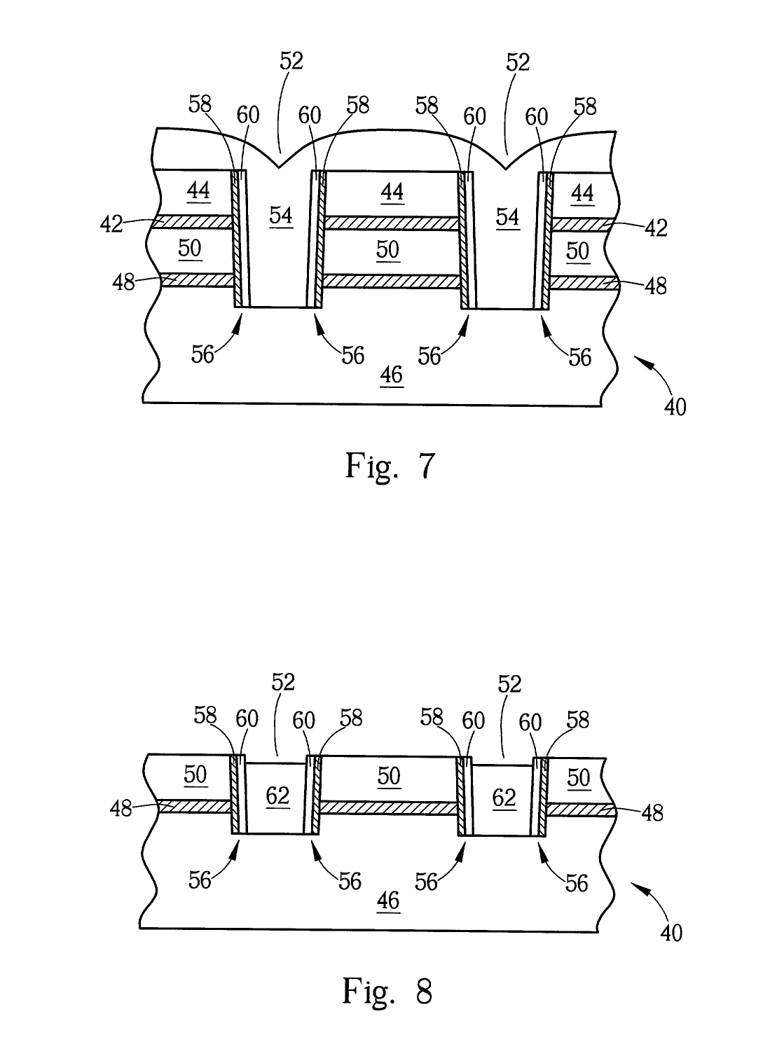

As shown in FIG. 7, a reactive ion etching (RIE) process is performed to remove portions of the second insulator layer 56 at the bottom of the contact hole 52 and to remove the liner nitride layer 50 on the surface of the SOI wafer 40. Next, a polysilicon layer 54 is formed to cover the surface of the SOI wafer 40 and fill the contact hole 52. As shown in FIG. 8, a chemical mechanical polishing (CMP) process and an etching back process are then performed to remove the silicon oxide layer 42, silicon nitride layer 44 and portions of the polysilicon layer 54 covering the silicon layer 50. The remaining portions of the polysilicon layer 54, of which its surface is almost aligned with the top of the contact hole 52, within the contact hole 52 is used as a substrate contact electrode 62.

In comparison with the prior art, the method of forming a substrate contact electrode in a SOI wafer according to the present invention allows for bias adjustment of the SOI substrate, to prevent electrical current accumulation caused by the first insulator layer. As a result, the operation and the function of the device are more efficient.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of forming a substrate contact electrode in a silicon-on-insulator (SOI) wafer, the SOI wafer comprising a substrate, a first insulator layer and a silicon layer covering the substrate, respectively, the method comprising:
etching a contact hole from a surface of the first insulator layer through to the substrate;
forming a second insulator layer covering a surface of the SOI wafer, as well as covering an interior wall and a bottom surface within the contact hole;
removing portions of the second insulation layer from the bottom surface within the contact hole;
forming the substrate contact plug in the contact hole; and
performing a first ion implantation process to form a well in the SOI wafer.

2. The method of claim 1 wherein the silicon layer has a thickness of about 1000 angstroms.

3. The method of claim I wherein the method of forming the contact hole comprises:
forming a pad oxide layer on the silicon layer;
forming a silicon nitride layer on the pad oxide layer;
performing a photolithographic process to form patterns of the contact hole on a surface of the silicon nitride layer; and
using remaining portions of the silicon nitride layer as a hard mask to perform an etch process to form the contact hole.

4. The method of claim 1 wherein the second insulator layer comprises both a liner oxide layer and a liner silicon nitride layer, respectively.

5. The method of claim 4 wherein the method of forming the second insulator layer comprises:
performing a thermal oxidation process to form a liner oxide layer on both the interior wall and on the bottom surface within the contact hole; and
performing a chemical vapor deposition (CVD) process to form the liner silicon nitride layer on both the liner oxide layer and on the surface of the SOI wafer.

6. The method of claim 1 wherein a reactive ion etching (RIE) process is used to remove the second insulator layer covering the bottom surface within the contact hole.

7. The method of claim 1 wherein the method of forming the substrate contact electrode comprises:
forming a polysilicon layer on the SOI wafer and filling in the contact hole;
performing a chemical mechanical polishing (CMP) process on a surface of the polysilicon layer; and
performing an etch back process to remove portions of the polysilicon layer, to make the surface of the polysilicon layer align with a top of the contact hole so as to form the substrate contact electrode.

8. The method of claim 1 wherein the method further comprises a second ion implantation process, following the first ion implantation process, to dope a region adjacent to the interface of the substrate and the substrate contact electrode.

9. A method of forming a substrate contact electrode in a silicon-on-insulator (SOI) wafer, the SOI wafer comprising a substrate, a first insulator layer and a silicon layer covering, respectively, the method comprising:
etching a contact hole from a surface of the first insulator layer through to the substrate;
forming a liner oxide layer covering an interior wall and a bottom surface within the contact hole;
forming a liner silicon nitride layer on both the liner oxide layer and on the SOI wafer;
removing portions of both the liner oxide layer and the liner silicon nitride layer from the bottom surface within the contact hole;
forming the substrate contact plug in the contact hole;
performing a first ion implantation process to form a well in the SOI wafer; and
performing a second ion implantation process to dope a region adjacent to the interface of the substrate and the substrate contact electrode.

10. The method of claim 9 wherein the silicon layer has a thickness of about 1000 angstroms.

11. The method of claim 9 wherein the method of forming the contact hole comprises:
forming a pad oxide layer on the silicon layer;
forming a silicon nitride layer on the pad oxide layer;
performing a photolithographic process to form patterns of the contact hole on a surface of the silicon nitride layer; and
using remaining portions of the silicon nitride layer as a hard mask to perform an etch process to form the contact hole.

12. The method of claim 9 wherein a thermal oxidation process is used to form the liner oxide layer.

13. The method of claim 9 wherein a chemical vapor deposition (CVD) process is used to form the liner silicon nitride layer.

14. The method of claim 9 wherein the reactive ion etching (RIE) process is used to remove the second insulator layer covering the bottom surface within the contact hole.

15.The method of claim 9 wherein the method of forming the substrate contact electrode comprises:
forming a polysilicon layer on the SOI wafer and filling in the contact hole;
performing a chemical mechanical polishing (CMP) process on a surface of the polysilicon layer; and
performing an etch back process to remove portions of the polysilicon layer, to make the surface of the polysilicon layer align with a top of the contact hole so as to form the substrate contact electrode.
